(19) United States
(12) Patent Application Publication
(10) Pub. No.: US 2026/0144126 A1
(43) Pub. Date: May 21, 2026

(54) MODULE-CARRIER TAPE

(71) Applicant: GIESECKE+DEVRIENT EPAYMENTS GMBH, Munchen (DE)

(72) Inventor: Stefan KLUGE, Munchen (DE)

(21) Appl. No.: 19/117,471

(22) PCT Filed: Oct. 11, 2023
(86) PCT No.: PCT/DE2023/100757

§ 371 Date: Apr. 1, 2025

(30) Foreign Application Priority Data
Oct. 12, 2022 (DE) 10 2022 003 764.5

(51) Int. Cl. H10W 74/10; G06K 19/077; H10W 74/01

(52) U.S. Cl. CPC H10W 74/114; G06K 19/07747; H10W 74/01

(57) ABSTRACT

A method is for applying an adhesive layer to a module-carrier tape provided with a plurality of chip modules including: surfaces of the chip modules being elevated concerning the surface of base areas of the module-carrier tape substantially surrounding the plurality of chip modules: forming tabs in the adhesive layer such that the tabs correspond to the chip modules or their protective layers of the module-carrier tape; connecting the adhesive layer to the module-carrier tape such that the tabs rest on the surfaces of the chip modules and sections of the adhesive layer adjoining the tabs rest on the base areas of the module-carrier tape. Also disclosed are a device for applying an adhesive layer to a module-carrier tape provided with chip modules, a module-carrier tape connected to an adhesive layer, an adhesive layer, and a method for producing a portable data carrier, and a portable data carrier.

The present invention relates to a method and a device for applying an adhesive layer to a module-carrier tape provided with a plurality of chip modules. Furthermore, the invention relates to a corresponding adhesive layer and a module-carrier tape provided with such an adhesive layer. Finally, the invention relates to the production of a portable data carrier starting from a module-carrier tape according to the invention and also a corresponding portable data carrier.

Equipping portable data carriers, such as chip cards or smart cards, with integrated circuits (ICs), chips, and/or microprocessors is known, in order to provide users with electronically secured functionalities, such as the option of carrying out secured financial transactions, establishing identities and access authorizations, or the like. In addition, further electronic functional units can be integrated into portable data carriers, such as memory chips, antennas, and coils or displays. Such portable data carriers are generally biometric cards, dual interface cards, personal ID cards, debit or credit cards, key cards or identity cards, or the like.

In addition, such portable data carriers are often equipped with security features for identifiability and improved forgery security, for example, in the form of letters or numbers, embossed structures, optically variable lenses or lattice structures, or the like.

In the series production of such data carriers, the chips thereof are inserted in the form of so-called chip modules into precisely-fitted cavities of the corresponding data carrier bodies and contacted with the electronic structures embedded in the data carrier body, for example, with coils, antennas, sensors, displays, or the like.

For this purpose, initially module-carrier tapes having a plurality of chip modules arranged regularly thereon are provided, onto which an adhesive layer provided with contact openings is precisely applied in such a way that the openings expose the contacts of the chip modules for the later contacting. The subsequently isolated chip modules are then adhesively bonded by means of the adhesive layer sections applied thereon in the cavities of the data carrier bodies such that the upper side of the module carrier terminates essentially with the surface of the data carrier body.

In contrast to the planar adhesive layer, such a module-carrier tape has a three-dimensional height/depth structure due to the raised chip modules, which varies between the elevated surfaces of the chip modules and the lower-lying base areas of the module-carrier tape surrounding them. The entire surface of the module-carrier tape to be spanned is therefore larger than the base area of the planar adhesive layer to be applied thereon.

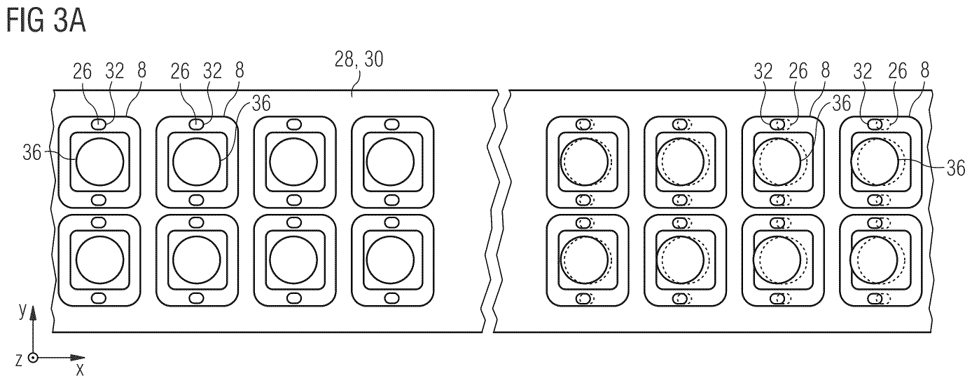

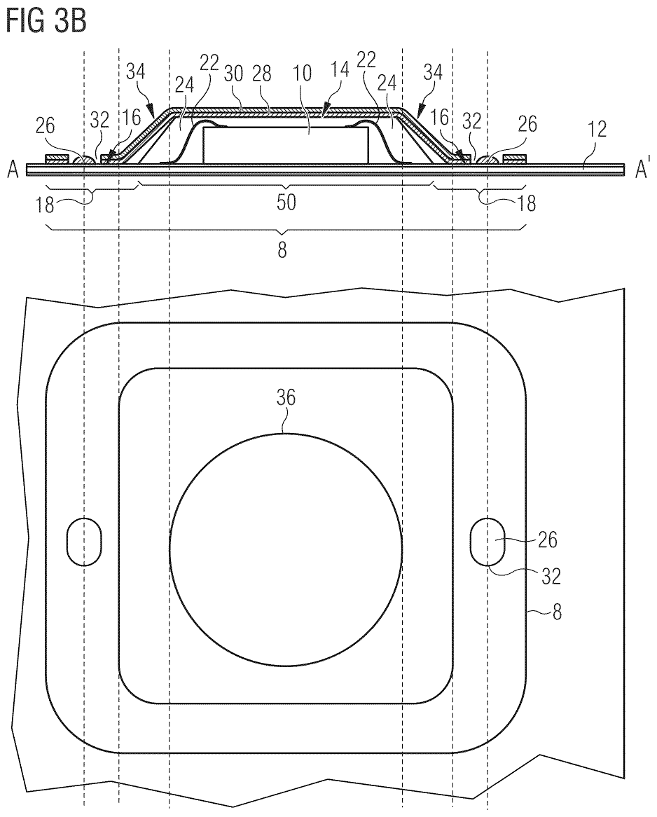

As illustrated in FIG. 3A, it can therefore occur that during the application of an adhesive layer 28, for example, in that it is unrolled from a roll in the longitudinal direction onto the module-carrier tape, an offset which becomes larger in the longitudinal direction, as indicated by dashed lines in FIG. 3A, arises, which has the result that the openings 32, 36 of the adhesive layer 28, which are initially matched precisely in position with the chip modules 8 and the contacts 26 thereof, no longer fit after a few meters. Leaving open the complete chip module area 8 in the adhesive layer 28 by way of central large holes 36 and applying such an adhesive layer 28 only on the surrounding base areas of the module-carrier tape is problematic in process technology, since then the contact openings 32 of the adhesive layer 28 are no longer surrounded by enough adhesive layer material, so that the adhesive layer 28 becomes unstable and the chip module 8 could finally even be removed again from the data carrier body. FIG. 3B illustrates these problems by means of the comparison, with correct dimensions, of a section of the adhesive layer 28 of FIG. 3A and the chip module 8 of FIG. 2, which is described hereinafter.

The invention is therefore based on the object of proposing a solution for the above-mentioned technical problems, which enables an adhesive layer to be applied precisely in position on a module-carrier tape equipped with a plurality of chip modules, so that contacts of the isolated chip modules remain free and a sufficiently high level of adhesion is ensured.

This object is achieved according to the invention by a method as claimed in claim 1. A corresponding device according to the invention for applying an adhesive layer to a module-carrier tape, a module-carrier tape connected to an adhesive layer, an adhesive layer according to the invention, and also a method for producing a portable data carrier and such a data carrier are the subject matter of further independent claims. Advantageous refinements of the invention are specified in the dependent claims.

According to a first aspect, a method for applying an adhesive layer to a module-carrier tape provided with a plurality of chip modules is provided. The chip modules, which are provided with the adhesive layer and are isolated later, are introduced into security documents, for example, into card-shaped data carriers or security documents in sheet form.

The module-carrier tape is formed planar; it can comprise, for example, a film tape. The module-carrier tape is generally embodied as stiff, thus essentially inelastic. The module-carrier tape can be formed flat. For example, the module-carrier tape is continuously planar and/or flat. The module-carrier tape can have a thickness of greater than 0.5 mm, for example, a thickness of one or more millimeters, in particular a thickness of 3.5 mm.

A plurality of chip modules is arranged on the module-carrier tape, which comprise chip-shaped electrical components or semiconductor structures. The chip modules and therefore the module-carrier tape can comprise encapsulations or protective layers or further layers, which each cover and/or encapsulate the chip-shaped components. The module-carrier tape can comprise bond wires, which are connected to the respective chip-shaped components. The bond wires can also be enclosed by the encapsulations.

The surfaces of the chip modules are elevated in relation to the surfaces of the respective surrounding base areas of the module-carrier tape. These surrounding base areas of the module-carrier tape are to be understood as areas of the module-carrier tape which extend around the chip modules (for example, in a top view of the module-carrier tape) or are located adjacent to the chip modules and/or adjoin the chip modules. The surfaces of the chip modules can be essentially parallel to and spaced apart from the surface of the surrounding base areas of the module-carrier tape. The chip modules can therefore have the shape of lumps on the module-carrier tape.

The method comprises a step of forming one or preferably multiple tabs in the adhesive layer, in that the tabs are detached or separated from surrounding areas of the adhesive layer. The mentioned surrounding areas of the adhesive layer are to be understood as those areas of the adhesive layer which, after the formation of the tabs, are located around them or adjacent to them and/or are opposite to outer edges of the tabs. The tabs can be formed as sections in the adhesive layer which are movable relative to the remaining adhesive layer, for example, can be angled or bent, without the adhesive layer having to be stretched in this case. The tabs can comprise one or more free edges or outer edges.

The tabs are formed in the adhesive layer such that they correspond to the chip modules of the module-carrier tape. That is to say, the relative positions of the tabs formed in the adhesive layer correspond to the relative positions of the chip modules on the module-carrier tape, so that the tabs each come to rest on chip modules when the adhesive layer is connected to the module-carrier tape.

In this sense, the method according to the invention furthermore comprises a step of connecting the adhesive layer to the module-carrier tape such that the tabs each rest (at least or only) on the surfaces of the chip modules elevated in relation to the module-carrier tape. Accordingly, the sections of the adhesive layer each adjoining the tabs (only) rest on the base areas of the module-carrier tape. In this way, the adjoining areas of the adhesive layer are fastened on the base areas of the module-carrier tape and the tabs are possibly each fastened on the corresponding chip modules. In particular, the occurrence of an offset during the unrolling in the longitudinal direction is substantially avoided, because the tabs substantially compensate for the spanned surface of the module-carrier tape, which is elevated in relation to the base area of the adhesive layer. The chip modules and their contacts remain precisely fitted to the openings of the adhesive layer over the entire length in this way.

The adhesive layer is preferably heated to connect the adhesive layer to the module-carrier tape. The adhesive layer can insofar be a hotmelt adhesive. To fasten the tabs on the surfaces of the chip modules, the tabs can be pushed or pressed onto the chip module surfaces, for example, by a suitable heat-conducting stamp. The adjoining sections of the adhesive layer are connected correspondingly to the base areas of the module-carrier tape, in that they are also pushed or pressed on, for example, by the same heat-conducting stamp.

The method can furthermore comprise a step of forming contact openings in the adhesive layer. The contact openings are introduced into the adhesive layer such that they correspond to the electrical contacts of the chip modules of the module-carrier tape. During the connection of the adhesive layer to the module-carrier tape, the contact openings surround the electrical contacts of the chip modules such that the electrical contact elements remain uncovered and are accessible and can be contacted even after application of the adhesive layer.

The contact openings are exclusively provided in the further areas of the adhesive layer. The contact openings can be formed completely or at least partially in the sections of the adhesive layer adjoining the tabs. The contact openings do not cut outer edges of the tab, for example. The contact openings do not represent, for example, outer edges or sections of outer edges of the tabs.

The chip modules can be electrically connected to other functional elements via the electrical contact elements, for example, to functional elements of portable data carriers or security documents, in which the isolated chip modules are used later. The electrical contact elements can be electrode pads or connection electrodes. A plurality of such electrical contact elements can be arranged on the module-carrier tape, in particular, for example, two, four, six, or ten electrical contact elements per chip module. The contact elements can be arranged around the respective chip modules, for example, symmetrically in a top view of the module-carrier tape. A contact opening is preferably formed for each of these electrical contact elements in the adhesive layer, which is arranged on the relevant contact element upon the connection of the adhesive layer to the module-carrier tape, so that this contact element remains uncovered by the adhesive layer.

The tabs can be formed by means of the introduction of openings into the adhesive layer. According to one preferred embodiment of the invention, the tabs are formed by means of the introduction of cutting patterns into the adhesive layer. In this way, cutting patterns each form the tabs and their adjoining sections in the adhesive layer such that the cutting patterns expand to form openings upon connection of the adhesive layer to the module-carrier tape, so that the adhesive layer can also rest on flanks of the chip modules which form the transitions from the elevated surfaces of the respective chip modules to the surface of the base areas of the module-carrier tape. The sections of the adhesive layer adjoining the tabs then rest on the base areas of the module-carrier tape and the expansion of the cutting pattern to form visible openings creates a flexibility or a material excess of the adhesive layer which permits the adhesive layer to also cover the flanks of the chip modules, in addition to the surfaces of the chip modules and the base areas of the module-carrier tape.

The flanks of the chip modules can be covered in this case with a part of the tabs, while or because the cutting patterns expand to form openings. The larger surface of the module-carrier tape in comparison to the adhesive layer due to the elevated chip modules can thus be completely covered according to the invention by the adhesive layer, since openings expand upon the connection of the adhesive layer to the module-carrier tape along the cutting pattern, which compensate for the larger surface of the module-carrier tape.

The cutting patterns can advantageously be introduced into the adhesive layer in particular such that the relevant openings expose those areas of the chip modules which are to be kept clear, for example, for thermal, sensorial, or other electrical reasons. These openings can also minimize mechanical tensions in the adhesive layer.

The adhesive layer is thus preferably connected to the module-carrier tape such that only the tabs of the adhesive layer rest on the surfaces of the respective chip modules and substantially completely cover them, for example. Alternatively or additionally, the tabs can also rest on the flanks of the relevant chip modules, thus on the transitions from the elevated chip module surfaces to the surface of the base areas of the module-carrier tape.

In this way, according to the invention, the adhesive layer rests over the full surface on the module-carrier tape, because the tabs or the corresponding cutting patterns enable the adhesive layer to adapt to the elevated chip modules without wrinkling or stretching or incorrect positioning of the adhesive layer on the module-carrier tape occurring.

The adhesive layer can be arranged on a carrier film, which can be provided in roll form and can be unrolled before the formation of the tabs. The carrier film can initially remain on the adhesive layer after the connection of the adhesive layer to the module-carrier tape and can be used at least temporarily as a cover layer.

However, the method preferably comprises a step of pulling the carrier film off of the adhesive layer after the connection of the adhesive layer to the module-carrier tape, in order to expose the adhesive layer. The adhesive layer can be formed as a hotmelt adhesive tape. The adhesive layer and/or the carrier film is preferably inelastic or substantially inelastic. The adhesive layer can be connected to the module-carrier tape and the chip modules by means of heat transfer.

The design of the adhesive layer as a transfer layer permits a very thin adhesive layer to be provided. A reliable formation of the tabs can also be ensured in this way, since the adhesive layer is arranged on the carrier film and/or is supported by the carrier film during the formation of the tabs.

The carrier film can be pulled off beginning with a section of the module-carrier tape located at the rear in the pulling-off direction in the direction of a section of the module-carrier tape located at the front in the pulling-off direction, for example, after the adhesive layer designed as a transfer layer has been connected to the module-carrier tape. The carrier film is pulled off or smoothly separated from the adhesive layer in this manner.

The tabs resting on the chip modules can point with their distal or free ends in predetermined directions in each case. A predetermined direction is to be understood in this context as a direction which points starting from the sections of the adhesive layer adjoining the tabs toward the respective distal or free end of the tabs. A distal or free end is in this context, for example, an end of the tab facing away and/or spaced apart from the section of the adhesive layer adjoining the relevant tab.

The predetermined directions of the distal ends of the tabs each meet one of the following conditions, for example: (i) the predetermined direction is orthogonal to the pulling-off direction; (ii) the predetermined direction extends at an acute angle in relation to the pulling-off direction; (iii) the predetermined direction corresponds to the pulling-off direction.

The carrier film is, for example, first pulled off from the sections of the adhesive layer adjoining the tabs and then pulled off from the tabs themselves. The carrier film is first pulled off from the distal ends of the tabs, for example, after it has been pulled off from the remaining areas of the tabs. The carrier film can in particular be pulled of such that the carrier film is detached simultaneously from the adhesive layer at all of those points which are located on a straight line (in particular extending orthogonally to the pulling-off direction) extending fixedly in relation to the pulling-off direction. For example, an area of the carrier film resting on a tab detaches simultaneously from the respective tab at all of those points which lie on a straight line (in particular extending orthogonally to the pulling-off direction) extending fixedly in relation to the pulling-off direction.

For example, the tabs exclusively or at least predominantly have outer edges which each meet one of the following conditions: (i) the relevant outer edge extends parallel to the pulling-off direction; (ii) the relevant outer edge extends at an obtuse angle in relation to the pulling-off direction; (iii) the relevant outer edge extends curved, for example, in the form of a curve or arc, wherein tangents of the outer edge extend parallel or at an acute angle to the pulling-off direction.

A tab according to the invention or each tab of the adhesive layer according to the invention can comprise at least one pair, for example, three or five pairs, of outer edges adjoining one another, wherein the outer edges of the at least one pair extend diagonally relative to one another, wherein a corner lying between the outer edges of the at least one pair is rounded, for example. The tab exclusively comprises rounded corners, for example, thus no pointed or non-rounded corners.

Complete or residue-free pulling of the carrier film off of the adhesive layer can be ensured by these designs. Tearing of the carrier film and/or the adhesive layer can also be avoided. Furthermore, the risk of detaching the adhesive layer from the module-carrier tape or the chip modules is minimized or at least significantly reduced.

The tabs can be formed mirror-symmetrical. The tabs can be formed V-shaped or U-shaped. The tabs can each comprise two outer edges extending in parallel. The tabs can each be formed in different shapes, for example, in the form of triangles, rectangles, trapezoid, or rectangles each having triangles placed thereon. In this case, the respective section of the adhesive layer adjoining one of the tabs represents one side of the relevant geometric shape. The tabs can be formed so that their widths each decrease in the direction of a distal end of the respective tab, for example, monotonously or strictly monotonously. The widths of the tabs can each continuously decrease in the direction of the distal end of the relevant tab. The widths of the tabs can in particular decrease from the respective sections of the adhesive layer adjoining the tabs to a respective area of the tabs (for example, the distal end) spaced apart from this section, in particular most remote therefrom. The tabs can taper in the direction of the relevant distal end.

Such shapes of the tabs have proven to be advantageous for achieving the above-mentioned object. Such shapes of the tabs also maximize or significantly simplify the pulling off of the carrier film.

According to the present invention, openings or cutting patterns forming the tabs can be introduced into the adhesive layer by a cutting method (for example, by means of a cutter, a laser, or a liquid jet) or by a punching method (for example, by means of a punching tool). The same also applies to the formation of the contact openings and further openings or apertures to be formed in the adhesive layer.

It is obvious that the carrier film can also be cut or punched during the cutting or punching of the adhesive layer. Tabs can thus also be cut or punched into the carrier film which correspond to the tabs of the adhesive film. It is also possible to form openings and/or cutting patterns in the carrier film which correspond to the openings and/or cutting patterns of the adhesive film.

During the connection of the adhesive layer to the module-carrier tape, the tabs are pushed, pressed, or adhesively bonded onto the surface of the chip module or a potting compound of the chip module, for example. According to one example, simultaneously with the relevant tabs, the tabs of respective adjoining sections of the adhesive layer are also pushed, pressed, or adhesively bonded onto the surface of the surrounding base areas of the module-carrier tape. Those sections of the adhesive film which come to rest on the flanks of the chip modules are also pushed or pressed thereon. The tabs can be pushed on with a lower pressure in this case than the sections of the adhesive layer adjoining the tabs.

A flexible stamp, in particular a stamp made of an elastic, heat-conductive material, can be used to push on or press on the tabs. The stamp can be manufactured from a suitable polymer, for example, from silicone. The stamp can be a part of a heated fixing tool. The fixing tool can comprise one or more fixing structures in areas surrounding the stamp, which push the adhesive layer, in particular the section of the adhesive layer adjoining the tab and/or the further areas or sections of the adhesive layer, onto the module-carrier tape, in particular onto the chip modules and their flanks, while the flexible stamp pushes the tabs onto the respective chip modules in one or a series of successive work steps. The fixing structures can consist of a harder material than the flexible stamp, for example, of metal or hard rubber.

Damage to the chip modules is avoided and secure fastening of the adhesive layer is achieved in this way.

In the method, the module-carrier tape and the adhesive layer can be moved in the same transport direction (for example, relative to the stamp or the fixing tool), and in particular at the same speed and/or with the same step size. The adhesive layer can be connected, for example, by means of lamination to the module-carrier tape and the chip modules.

According to a second aspect of the present invention, a device for applying an adhesive layer to a module-carrier tape provided with a plurality of chip modules is provided. The device comprises a processing unit which is configured to form tabs in an adhesive layer such that the tabs correspond to the chip modules of the module-carrier tape, to which the adhesive layer is subsequently to be connected. The processing unit can comprise a cutter, a laser, and/or a liquid jet device. The processing unit can alternatively or additionally comprise a punching tool. The device according to the invention furthermore comprises a connecting unit, which is configured to connect the adhesive layer to the module-carrier tape such that the tabs rest on the surfaces of the chip modules and sections of the adhesive layer adjoining the tabs rest on the base areas of the module-carrier tape. The connecting unit can be configured for heat transfer of the adhesive layer. The connecting unit can comprise the flexible, heat-conducting stamp described in conjunction with the first aspect and/or the fixing tool. In particular, the processing unit can also be implemented in a separate device which is structurally separate from the device which comprises the connecting unit.

The device is configured to carry out the method according to the first aspect. For this purpose, the device can comprise a pulling-off device, which is configured to pull off the carrier film. The processing unit can furthermore be configured to form the openings or cutting patterns and the contact openings. The device can be configured to move the module-carrier tape in a transport direction (for example, relative to the processing unit or the connecting unit) and to move the adhesive layer in the same transport direction, in particular at the same speed and/or with the same step size. The device can be configured to connect the adhesive layer by means of lamination to the module-carrier tape and the chip modules. The application of the adhesive layer to the individual chip modules or groups of chip modules in the context of the connection of the adhesive layer to the module-carrier tape preferably proceeds at the same speed and/or with the same step size with which the module-carrier tape is moved in the transport direction.

According to a third aspect of the invention, a module-carrier tape connected to an adhesive layer is provided, which is provided with a plurality of chip modules. The adhesive layer comprises tabs which correspond to the chip modules of the module-carrier tape and is connected to the module-carrier tape such that the tabs rest on the surfaces of the chip modules and sections of the adhesive layer adjoining the tabs rest on the base areas of the module-carrier tape. The adhesive layer additionally rests on the flanks of the chip modules, because the cutting patterns and/or openings provided therein permit the entire surface of the module-carrier tape, including all chip modules, to be covered by the adhesive layer without wrinkling or stretching.

According to a fourth aspect of the present invention, an adhesive layer is provided for connection to a module-carrier tape. The adhesive layer comprises tabs which are separated from the surrounding areas of the adhesive layer and can insofar be movable independently of the remaining adhesive layer. The adhesive layer is designed to be connected to the planar module-carrier tape, wherein chip modules are arranged on the module-carrier tape, the surfaces of which are elevated in relation to the base areas of the module-carrier tape. The tabs are formed so that they each correspond to the chip modules and can be fastened on the surfaces thereof. Sections of the adhesive layer adjoining the tabs can be fastened on the surrounding base areas of the module-carrier tape.

The adhesive layer can correspond to the adhesive layer described for the first aspect after the step of forming the tabs. The adhesive layer can be produced by the device according to the second aspect, in that the device forms the tabs. The adhesive layer can correspond to that according to the first aspect after the step of the formation of the cutting patterns and/or openings and/or contact openings. The adhesive layer, as explained for the first aspect, can be arranged on a carrier film and/or can be a hotmelt adhesive layer.

According to a fifth aspect of the present invention, a method is provided for producing a portable data carrier, which comprises a chip module. In the scope of this method, initially a data carrier body is provided, which comprises electrical structures having contacts which can be contacted via a cavity of the data carrier body. The cavity is intended and designed in this case such that it preferably accommodates the chip module in a precisely-fitted manner. According to a further step, a module-carrier tape provided with an adhesive layer according to the third aspect is provided and the chip module to be inserted into the cavity is isolated together with the connected adhesive layer using suitable cutting or separating means, so that the relevant chip module is, on the one hand, provided with the corresponding adhesive layer section and, on the other hand, is isolated from the further chip modules of the module-carrier tape. Finally, the isolated chip module is inserted into the cavity of the data carrier body such that the relevant adhesive layer section fixes the chip module firmly in the cavity and/or the chip module contacts the contacts of the electrical structures.

It is obvious that the above statements on the first aspect apply accordingly to the second, third, fourth, and fifth aspect. The definitions from the introductory part of the description are also applicable to all described aspects of the invention, and individual or all of the features described in the introductory part of the description can also be provided in the embodiments according to all aspects of the invention.

The present invention is described by way of example hereinafter with reference to the appended drawings, wherein the same reference signs indicate the same structural and/or functional features. In the figures:

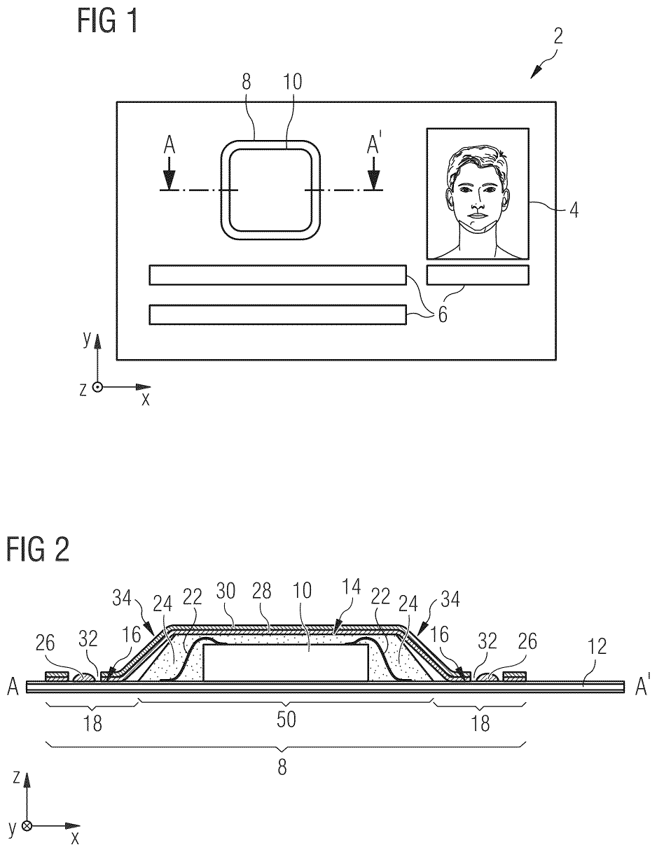

FIG. 1 shows a schematic representation of an exemplary security document;

FIG. 2 shows a schematic representation of a detail of a module-carrier tape which is provided with a chip module having a conventional adhesive layer;

FIG. 3A shows a schematic representation of a module-carrier tape having a plurality of chip modules and a conventional adhesive layer applied thereon;

FIG. 3B shows a correctly-dimensioned comparison of a section of the adhesive layer from FIG. 3A and the chip module from FIG. 2;

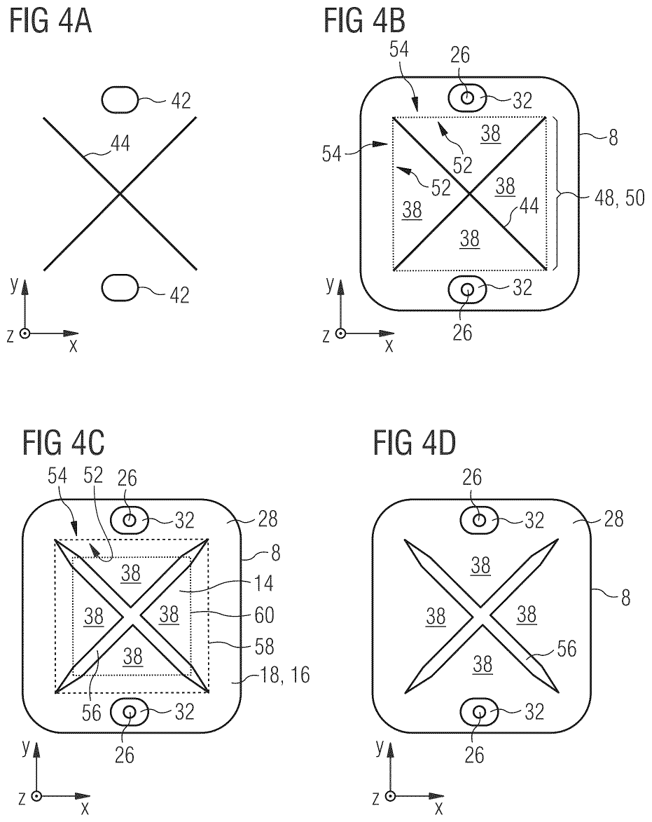

FIGS. 4A-4D show a preferred embodiment of a cutting pattern and an adhesive layer;

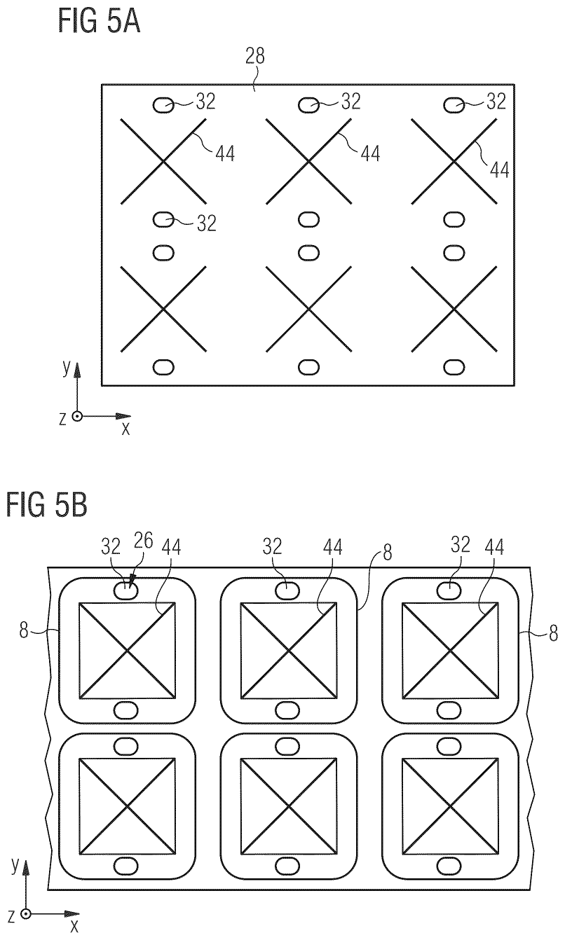

FIGS. 5A-5B show a preferred embodiment of an adhesive layer;

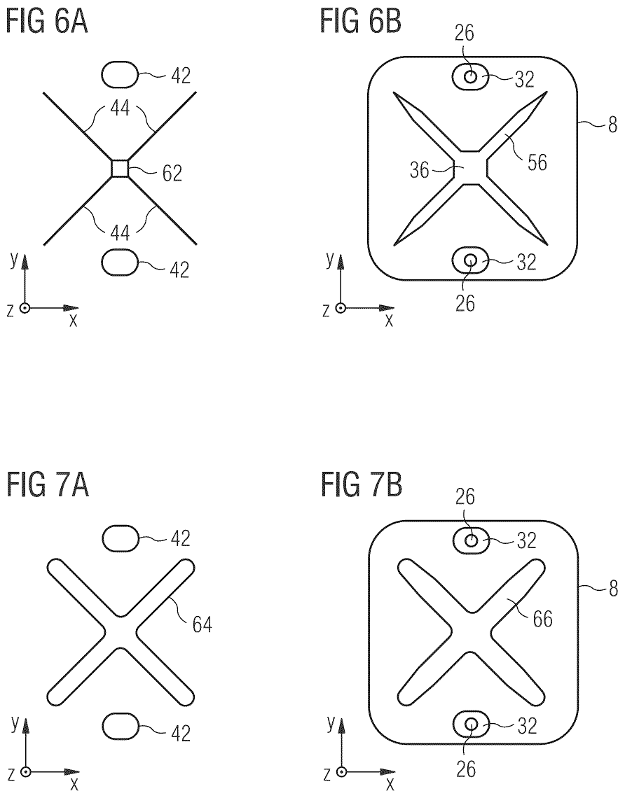

FIGS. 6A-6B show a preferred embodiment of a cutting pattern and an adhesive layer;

FIGS. 7A-7B show a preferred embodiment of a cutting pattern and an adhesive layer;

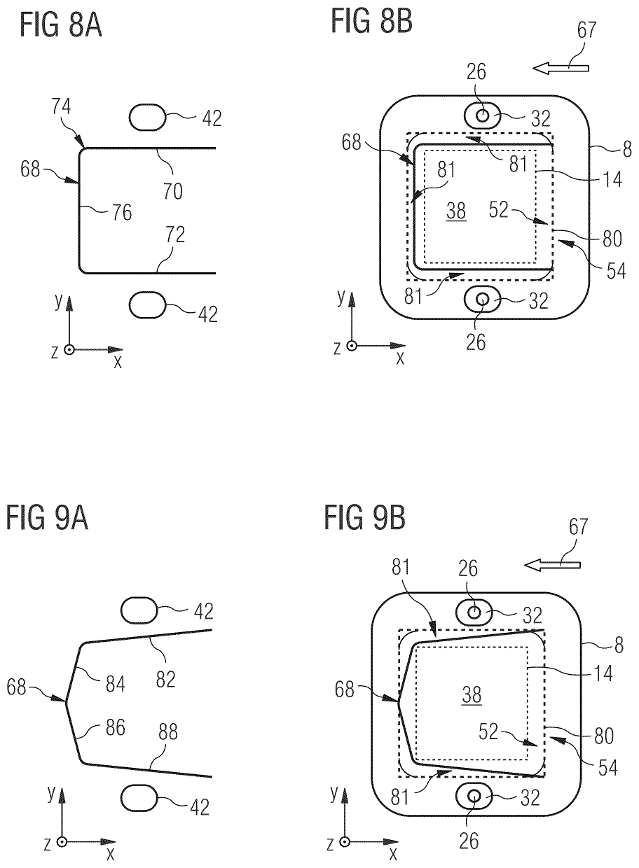

FIGS. 8A-8B show a preferred embodiment of a cutting pattern and an adhesive layer;

FIGS. 9A-9B show a preferred embodiment of a cutting pattern and an adhesive layer;

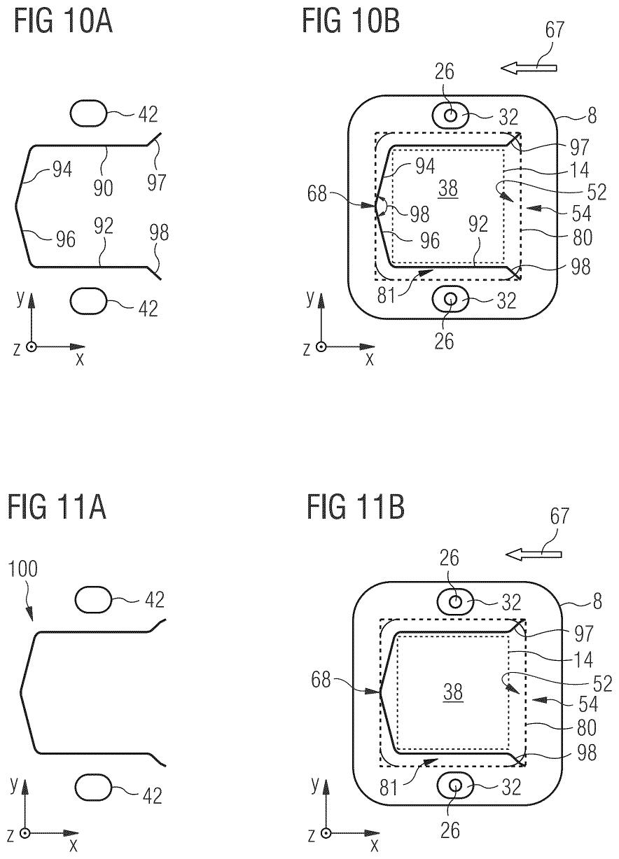

FIGS. 10A-10B show a preferred embodiment of a cutting pattern and an adhesive layer;

FIGS. 11A-11B show a preferred embodiment of a cutting pattern and an adhesive layer;

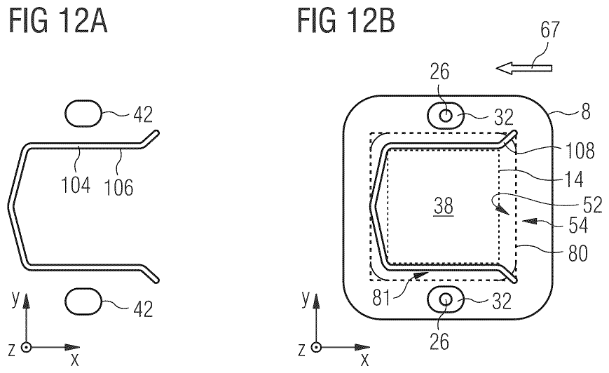

FIGS. 12A-12B show a preferred embodiment of a cutting pattern and an adhesive layer;

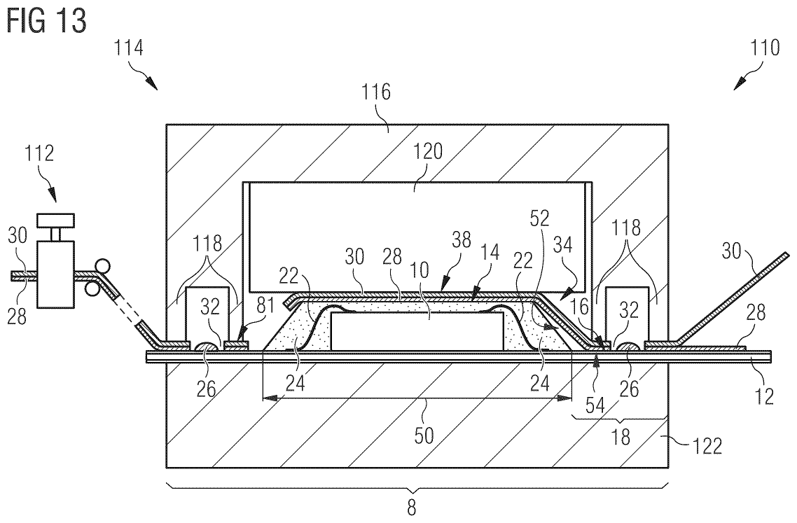

FIG. 13 shows a preferred embodiment of a fixing tool; and

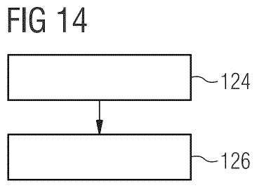

FIG. 14 shows a preferred embodiment of a method.

FIG. 1 shows an example of a portable data carrier in the form of a security document 2. The security document 2 is in this case a security card, e.g., a credit card, a key card, or an identification card, such as a personal identification. Other types of security documents are also conceivable, in particular security documents in sheet form such as banknotes, vouchers, or the like.

The security document 2 can comprise an image 4, for example, a passport picture of the bearer. Furthermore, the security document 2 can comprise written and numeric information 6, e.g., a name, a postal address, and/or a user identification of the bearer or information relating to the issuer of the security document.

The security document 2 comprises a three-dimensionally structured chip module 8 having a (micro-)chip 10 and/or further electronic components, such as integrated circuits (ICs), microprocessors, electronic memories, or the like. The chip module 8 can also comprise a sensor or further chips. For example, information is storable or stored in the chip 10, in particular on the bearer or issuer of the security document 2. The security document 2 can also comprise a sensor or a plurality of sensors which are connected to the chip 10. The sensor can be a fingerprint sensor or an optical scanner. In this case, the chip 10 can comprise a processor which processes data of the sensor or the plurality of sensors and outputs a processing result, for example, at an output unit (for example, a light-emitting diode or a display) of the security document 2 or at an external unit, for example, an identity checking unit (for example, by means of a wireless communication connection or broadcasting). According to alternative embodiments, the chip 10 itself can also be designed as a sensor, while the security document 2 has further chips and/or security elements.

FIG. 2 shows a cross section through the chip module 8 and its chip 10 during a production step for producing the security document 2.

It can be seen that the chip module 8 is arranged on a planar module-carrier tape 12. The chip module 8 has a surface 14, which is elevated due to or in the area of the chip 10 in relation to a surface 16 of the module-carrier tape 12. The surface 16 is the surface of a base area 18 of the module-carrier tape 12 adjoining the chip module 8. The chip module 8 comprises the chip 10, to which bond wires 22 are connected. The chip 10 and the bond wires 22 can be encapsulated by an encapsulation or protective layer 24. The protective layer 24 can be, for example, a cured epoxy resin or another suitable potting compound which forms the surface 14 of the chip module 8. Electrical contact elements 26, which can each be connected to one or more of the bond wires 22, are arranged on the module-carrier tape 12.

In order to be able to insert the chip module 8 firmly into a suitable data carrier body later and thus form a security document 2 according to FIG. 1, an adhesive layer 28 is applied to the module-carrier tape 12 and the chip module 8 for the later adhesion between the chip module 8 and the data carrier body. For example, this adhesive layer 28 is a hotmelt adhesive layer formed as a transfer layer, which is provided on a carrier film 30 as shown in FIG. 2. According to this example, the adhesive layer 28 and the carrier film 30 are each continuous layers or films, into each of which openings or contact openings 32 lying one on top of another are introduced. The contact openings 32 can be arranged during the connection of the adhesive layer 28 to the module-carrier tape 12 and to the chip module 8 so that the contact openings 32 lie above the electrical contact elements 26. In this way, it is ensured that no part of the adhesive layer 28 is arranged on the electrical contact elements 26, the latter thus remain free and can be contacted upon the later introduction into a data carrier body. To connect the adhesive layer 28 to the module-carrier tape 12, sections of the carrier film 30 and the adhesive layer 28 can be pushed onto the module-carrier tape 12, in particular onto the surface 14 and the surface 16 of the surrounding base areas 18.

As shown in FIG. 2, a larger area has to be spanned by the adhesive layer 28 and by the carrier film 30 than by the module-carrier tape 12, because the adhesive layer 28 and the carrier film 30 do not extend continuously parallel with the module-carrier tape 12 due to the elevated chip module 8 or its potting compound 24. A larger area of adhesive layer 28 is thus required due to the elevated shape of the three-dimensionally structured chip module 8 in relation to the surface 16 in comparison to the correspondingly spanned base area of the module-carrier tape 12.

In known methods for applying the adhesive layer 28 to the module-carrier tape 12, typically the same area of adhesive layer 28 is used as the base area of the module-carrier tape 12 to be spanned. The raised three-dimensional structure of the chip module 8 typically remains unconsidered. Therefore, a significant offset between the adhesive layer 28 and the module-carrier tape 12 can occur upon the connection of the adhesive layer 28 to the module-carrier tape 12 and to the elevated chip module 8, which in particular has the result that the adhesive film 28 is incorrectly positioned relative to the chip module 8 and/or the electrical contact elements 26. This disadvantageous phenomenon is schematically shown in FIG. 3.

In FIG. 3, which was already mentioned at the outset, the adhesive layer 28 is shown as a web material. The adhesive layer 28 is arranged on the carrier film 30 and can be kept ready on a roll. Contact openings 32 are introduced into the adhesive layer 28 and the carrier film 30. In addition, openings 36 are introduced into the adhesive layer 28 and the carrier film 30. The contact openings 32 are to be positioned over the electrical contact elements 26 and the openings 36 are to be positioned centrally over the chip module 8 on the surface 14.

The individual chip modules 8 are arranged on a continuous module-carrier tape 12. The chip modules 8 can be isolated after the application of the adhesive layer 28. Each of the chip modules 8 can be used to produce a portable data carrier, for example, of the security document 2, for example, by inserting, laminating in, or fastening on/in a part of the security document 12, for example, in a suitable cavity.

Beginning with the end shown at the left in FIG. 3, the adhesive layer 28 and the carrier film 30 are applied to a module-carrier tape 12 having a plurality of regularly spaced-apart chip modules 8. It can be seen that due to the increased need for adhesive layer 28 for covering the elevated chip modules 8, a progressive offset between the contact openings 32 and openings 36, on the one hand, and the contact elements 26 and chip modules 8, on the other hand, occurs along the longitudinal direction of the adhesive layer 28. The offset occurring due to a single chip module 8 is small, but the offset adds up along the application direction (thus toward the right in FIG. 3) in the course of time so that the chip modules 8 even become unusable, since the misalignment between the adhesive layer 28 and the module-carrier tape 12 or its chip modules 8 forms production flaws. For example, as a result of the offset, the electrical contact elements 26 could be partially or completely covered by the adhesive layer 28, and/or the opening 36 could be placed partially or completely outside or adjacent to the surface 14.

According to the present invention, an adhesive layer 28 is provided which is to be connected to a module-carrier tape 12 and which comprises tabs 38 for this purpose, which correspond to the chip modules 8 of the module-carrier tape 12. In particular, it is provided that the tabs 38 are formed by separating the tabs 38 from the surrounding areas of the adhesive layer 28, for example, due to cutting patterns and/or openings 32, 36 suitably introduced into the adhesive layer 28. The tabs 38 can be created in various ways, as can the contact openings 32 and/or the openings 36 as well as further openings. Thus, for example, punching methods or cutting methods can be used. When reference is made hereinafter to a punching pattern or a cutting pattern, this is to be understood as a pattern which can be introduced by punching or cutting into the adhesive layer 28 or which is left open during the production of the adhesive layer 28. The terms cutting pattern and punching pattern, cutting pattern section and punching pattern section, cut edge and punched edge, etc. are each used synonymously and are to comprise both cutting in and punching out.

FIGS. 4 and 6 to 12, which are described hereinafter, each show individual sections of a larger-area adhesive film 28, which are each provided to cover a single chip module 8 with contacts 26 of a larger-area module-carrier tape 12. All exemplary embodiments in this regard are thus to be understood to show an illustrative detail of a module-carrier tape 12, which comprises a plurality of chip modules 8, covered with an adhesive film 28.

FIG. 4A shows a punching or cutting pattern according to a preferred embodiment. This punching pattern is introduced into the adhesive layer 28 in order to form the tabs 38. Of course, the carrier film 30 can also be perforated simultaneously by the same cutting pattern. In FIG. 4A, on the one hand, a cross-shaped punching or cutting pattern 44 is introduced, which results in a corresponding cross-shaped perforation, by which four tabs 38 are formed. On the other hand, two contact openings 32, which are shown in FIG. 4B, are formed in the adhesive layer 28 by punching or cutting lines 42, which are closed as such. The contact openings 32 are, for example, circular, elliptical, or rounded.

FIG. 4B shows a view of the adhesive layer 28 which was provided with the punching pattern 44 from FIG. 4A. Furthermore, a chip module 8 is indicated, on which the adhesive layer 28 is to be fastened. It can be seen that the cross-shaped perforation is dimensioned along the punching pattern 44 so that the width 48 of the triangular tabs 38 corresponds in each case to the width 50 of the elevated area (corresponding to the surface 14) of the chip module 8 to be covered. In the illustrated example, the outer edges of the cuboid elevated area lie between attachment areas 52 of the individual tabs 38 and sections 54 of the adhesive layer 28, wherein each of the attachment areas 52 adjoins one section 54 of the adhesive layer 28 in each case.

When the sections 54 are pushed onto the surface 16 of the module-carrier tape 12, the individual tabs 38 can be expanded or folded upward. This is schematically shown in FIG. 4C. The tabs 38 are bent upward by the elevated chip module 8 such that a free space 56 forms between the individual tabs 38. In FIG. 4C, bending lines 58 and 60 of the tabs 38 are shown by way of example. The outer bending line 58 corresponds in this example to an outer edge of the chip module 8 at the height of the surface 16 of the base areas 18 of the module-carrier tape 12. The inner bending line 60 corresponds to an outer edge at the height of the surface 14.

By pushing the tabs 38 onto the surface 14, the individual tabs 38 can be fastened on the surface 14 of the structure 8. The sections 54 adjoining the tabs 38 can be fastened on the module-carrier tape 12. The formation shown in FIG. 4D is thus ultimately obtained. This is a top view of the adhesive layer 28 applied to the chip module 8 and the module-carrier tape 12. It can be seen that in this example only the tabs 38 are arranged in the area of the chip modules 8. It can be ensured by the cross-shaped perforation 56 of the adhesive layer 28, or by the formation of the individual tabs 38 in the adhesive layer 28, that the adhesive layer 28 does not have to be stretched during the covering of the chip modules 8. An elevated area consumption of adhesive layer 28 due to the elevated chip module 8 is also prevented. Therefore, it can be ensured by the adhesive layer 28 according to FIGS. 4A to 4D that the offset illustrated in FIG. 3 is prevented or at least largely minimized.

FIG. 5A shows an example of an adhesive layer 28 according to the present invention. A plurality of the cutting or punching patterns 44 according to FIG. 4A were introduced in this case into the adhesive layer 28. The adhesive layer 28 comprises a plurality of tabs 38 and is configured to be applied to a plurality of chip modules 8. The adhesive layer 28 can be kept ready or arranged on the carrier film 30 and can in particular be formed as a hotmelt adhesive layer. In particular, the adhesive layer 28 and the carrier film 30 can be formed as roll material. FIG. 5B shows the arrangement of the adhesive layer 28 from FIG. 5A on a plurality of chip modules 8. It can be seen that the individual tabs 38 rest on the relevant chip modules 8, and that the offset is negligible in comparison to the offset relating to a conventional adhesive layer 28 as explained in FIG. 3.

FIG. 6A shows a further preferred embodiment of a punching or cutting pattern 44 for introduction into the adhesive layer 28. It can be seen in comparison to FIG. 4A that in addition to the cross-shaped cutting pattern 44, a cutting line 62 which is closed per se is provided in the middle of the cross cut. The cutting line 62 can be used to introduce an opening 36 in the adhesive layer 28, which is arranged on the chip module 8. The shape of the adhesive layer 28 provided with the cutting pattern 44 according to FIG. 6A is shown after the application to a chip module 8 of the module-carrier tape 12 in FIG. 6B. It can be seen that the opening 36 is arranged centrally on the surface 14 of the chip module 8. The free space 56 also arises due to the folding of the individual tabs 38 upward (thus in the direction of the observer in FIG. 6B), as in the case of FIGS. 4E and 4D. Providing the opening 36 and/or the free space 56 prevents or minimizes stretches or stresses in the adhesive layer 28.

FIG. 7A shows a further possible cutting or punching pattern, which is introduced into the adhesive layer 28 and the carrier film 30. In this case, the punching pattern comprises a cross-shaped punching pattern section 64 which is closed per se. The punching pattern section 64 causes the formation of the tabs 38 upon punching into the adhesive layer 28. The punching pattern section 64 is formed planar, in contrast to the punching pattern section 44. The punching pattern section 64 causes the formation of an additional opening, which adjoins all outer edges of the individual tabs 38, upon introduction into the adhesive layer 28. The tabs 38 are thus formed by the introduction of the additional opening. FIG. 7B shows the arrangement of the adhesive layer 28 according to FIG. 7A on a chip module 8 of a module-carrier tape 12. The shape of the tabs 38 according to FIGS. 4A to 7B can be referred to as V-shaped.

The free space 66 in the adhesive layer 12 arising due to the introduction of the cutting pattern section 64 and the folding up of the tabs 38 is wider in comparison to the designs according to FIG. 4D and FIG. 6B, so that tensions within the adhesive layer 28 or an offset of the adhesive layer 28 in relation to the chip modules 8 and the substrate 12 can be further minimized, while a sufficient and uniform coverage of the structure 8 with the adhesive layer 28 can be ensured at the same time. The provision of a punching pattern section 64 formed as planar can also enable the use of a simple and cost-effective punching tool.

The carrier film 30 can be pulled off of the adhesive layer 28 after the adhesive layer 28 is connected to the module-carrier tape 12 and its chip modules 8. It is to be ensured in this case that the entire carrier film 30 is removed from the adhesive layer 28. In other words, after the carrier film 30 is pulled off, no residues are to remain on the adhesive layer 28. Experimental studies have shown that certain outlines and shapes of the tabs 38 enable reliable pulling off of the carrier film 30, while the above-mentioned advantages according to the invention are retained at the same time.

It is clear in conjunction with the embodiments according to FIGS. 8A to 12B that the carrier film 30 can be pulled off beginning with a section of the module-carrier tape 12 (or the adhesive layer 28) lying at the rear in a pulling-off direction 67 in the direction of a section of the module-carrier tape 12 (or the adhesive layer 28) lying at the front in the pulling-off direction 67, wherein a fastened tab 38 points with its distal end 68 in a predetermined direction. This predetermined direction can extend orthogonally to the pulling-off direction 67. Alternatively, the predetermined direction can extend in relation to the pulling-off direction 67 at an acute angle from the section lying at the rear to the section lying at the front. The predetermined direction can substantially correspond to the pulling-off direction 67. Alternatively or additionally, a tab 38 can have (for example, only) outer edges which each (i) extend parallel to the pulling-off direction 67, which (ii) extend at an acute angle in relation to the pulling-off direction 67, or which (iii) extend in a curve. In case (iii) each individual tangent of the outer edge extends parallel to the pulling-off direction 67 or extends at an acute angle in relation to the pulling-off direction 67.

Specifically, FIG. 8A shows a preferred embodiment of a cutting or punching pattern 74 having cutting edges 70, 72, 76. In this case, a single tab 38 is formed by the punching pattern 74, which rests or can be fastened on a chip module 8 or on its surface 14. The tab 38 (see FIG. 8B) introduced by the punching pattern according to FIG. 8A into the adhesive layer 28 is shaped so that when the carrier film 30 is pulled off in the pulling-off direction 67, first the section 54 of the adhesive layer 28 adjoining the tab 38 is freed from the carrier film 30, and then the tab 38 itself is freed from the carrier layer 30. According to FIG. 8B, the carrier film 30 is thus pulled off from right to left in the pulling-off direction 67. The tab 38 points with its distal end 68 away from the attachment area 52, which is located at a proximal end of the tab 38. The tab 38 is formed by severing areas 81 of the adhesive layer 28 located around the tab 38, in particular by forming an opening in the form of a perforation in the adhesive layer 28.

The two cut edges 70, 72 of the cutting pattern section 74 according to FIG. 8A extend parallel to the pulling-off direction 67. This causes the tab 38 to have a constant width and to be aligned parallel to the pulling-off direction 67. A further cut edge 76 extends orthogonally to the pulling-off direction 67. In this way, an outer edge of the tab 38, which is formed by the cut edge 76, abuts the distal end 68 of the tab 38 and extends orthogonally to the pulling-off direction 67. The shape of the tab 38 can be referred to as U-shaped. In FIG. 8B, the surface 14 and an outer edge 80 of the chip module 8 or its protective layer 24 are shown by dashed lines. The cutting or punching pattern is dimensioned there so that the tab 38 formed thereby covers the chip module 8 at least in the area of the surface 14 after the adhesive layer 28 is applied to the chip module 8. The tab 38 can be wider and/or longer than the surface 14 and in particular can also cover its flanks.

In the example according to FIGS. 8A and 8B, the attachment area 52 is narrower than the chip module 8, because the width of the tab 38 is less in the attachment area 52 than the width of the outer edge 80 of the chip module 8. However, it is also possible that the attachment area 52 has a width which corresponds to the width of the chip module 8 at a first side of the chip module 8, wherein the first side is closest to the attachment area 52 in comparison to other sides of the chip module 8. In the case of FIG. 8B, the attachment area 52 can thus have a width which corresponds to the length of the outer edge 80 of the chip module 8. Further embodiments are described hereinafter, in which these features can be implemented.

FIG. 9A shows a further preferred embodiment of a cutting or punching pattern having cut edges 82, 84, 86, 88. FIG. 9B shows the formation thus obtained. The shape of the tab 38 can be referred to as substantially U-shaped in each case. As in the case of the above-described V-shaped tabs 38, the width of the tab 38 shown in FIG. 9B decreases in the direction of the distal end 68. In comparison to FIG. 8A, all outer edges of the tab 38 extend in this case at an obtuse angle in relation to the pulling-off direction 67. The individual cut edges 82, 84, 86, 88 extend diagonally in relation to one another. An obtuse angle is formed between each pair of adjacent cut edges 82, 84, 86, 88. The areas of the cutting pattern at which the obtuse angles lie can be rounded. It can also be provided in the further embodiments described herein that an outer outline of the tab only comprises rounded corners.

In the case of FIG. 9A, the tab 38 points to the left with its distal end 68, the tab 38 thus also points in the pulling-off direction 67 here. It can thus be ensured that first the carrier layer 30 is pulled off from the area 54 of the adhesive layer 28 adjoining the tab 38, before the carrier layer 30 is pulled off from the tab 28. This increases the reliability of the pulling off and minimizes possible residues of the carrier film 30 on the adhesive layer 28.

FIG. 10A shows a further preferred embodiment of a cutting or punching pattern, comprising the cut edges 90, 92, 94, 96, 97, 98, and FIG. 10B shows a corresponding adhesive layer 28 having the introduced punching pattern of FIG. 10A. In this case, two outer sides 90, 92 of the tab 38 extend parallel to the pulling-off direction 67 and an obtuse angle 98 formed by two meeting outer edges 94, 96 is provided at the distal end 68 of the tab 38. Two outer edges 97, 98 protruding in the width direction in relation to the remaining areas of the tab 38 are provided at a proximal end 68 of the tab 38. These outer edges 97, 98 extend like the outer edges 90, 92 of the tab 38 adjoining thereon at an acute angle to the pulling-off direction 67. This embodiment also ensures that the surface 14 of the chip module 8 is completely covered by the tab 38 when the adhesive layer 28 is applied to the chip module 8 (see FIG. 10B).

FIG. 11A shows a further preferred embodiment of a cutting or punching pattern 100 and FIG. 11B shows an adhesive layer 28 having the punching pattern 100 shown in FIG. 11A. In this case, in comparison to FIG. 10B, the two outer edges 97, 98 protruding in the width direction in relation to the remaining areas of the tab 38 are not linear, but rather are curved. This embodiment also ensures that all tangents of the outer edges 97, 98 extend at an acute angle to the pulling-off direction 67 and the advantages according to the invention are achieved.

FIG. 12A shows a further preferred embodiment of a cutting or punching pattern and FIG. 12B shows an adhesive layer 28 having the punching pattern from FIG. 12A. The punching pattern of FIG. 12A differs from the punching pattern shown in FIG. 11A in that instead of a linear punching pattern 100, a planar punching pattern section 104 or a punching line 106 which is closed per se is provided, which defines the shape of the tab 38 in the adhesive layer 28. In other words, all outer edges of the tabs 38 are formed by the opening 108, wherein the opening 108 is introduced into the adhesive layer 28 by the punching pattern section 104 and/or the punching line 106.

The punching or cutting shapes described herein can be used to form the tabs 38 in the adhesive layer 28. After the formation of the tabs 38, the tabs 38 can be fastened on the surfaces 14 of the relevant chip modules 8 of the module-carrier tape 12. The sections 54 of the adhesive film 28 adjoining the tabs 38 are then fastened on the surfaces 16 of the base areas 18 of the module-carrier tape 12. The surface 14 of a chip module 8 can in this case comprise a surface section which is elevated most strongly in relation to the surface 16 of the surrounding base area 18 of the module-carrier tape 12 and in comparison to all other sections of the surface 14 of the chip module 8.

FIG. 13 schematically shows a device 110 for applying an adhesive layer 28 to a module-carrier tape 12 according to the present invention, which is provided with a plurality of chip modules 8. The device 110 comprises for this purpose a processing unit 112 and a connecting unit 114.

The processing unit 112 is configured to form tabs 38 in an adhesive layer 28. The processing unit 112 in particular comprises a punching or cutting tool, which introduces a punching or cutting pattern according to one of FIGS. 4A, 6A, 7A, 8A, 9A, 10A, 11A, or 12A into the adhesive layer 28, which is arranged on a carrier film 30, for example.

The adhesive layer 28 is then arranged or fastened by means of the connecting unit 114 module by module or progressively in another manner suitable for processing on the plurality of chip modules 8 of the relevant module-carrier tape 12. For this purpose, the connecting unit 114 comprises a fixing tool 116 having fixing elements, which are designed to push the adhesive film 28, suitably placed, onto the module-carrier tape 12. Furthermore, the fixing tool 116 comprises a flexible, heat-conducting stamp 120, for example, consisting of a suitable polymer, such as silicone. The flexible stamp 120 is designed to push each of the tabs 38 onto the surfaces 14 of the relevant chip modules 8, while simultaneously the fixing elements 118 push the adhesive layer 28 onto the module-carrier tape 12. During the pushing on, preferably both the fixing elements 118 and the stamp 120 are heated in order to cause or optimize the adhesion of the adhesive layer 28 on the chip module 8.

For example, the fixing tool 116 is actively heated and the stamp 120 passes on the heat to the tabs 38. The module-carrier tape 12 can be pushed by the fixing tool 116 onto a counter tool 122, so that the module-carrier tape 12 and the adhesive layer 28 are clamped between the fixing tool 116 and the counter tool 122. The adhesive layer 28 is thus fastened on the module-carrier tape 12 or the adhesive layer 28 designed as a transfer layer is transferred to the module-carrier tape 12.

After the connection of the adhesive layer 28 to the chip module 8 or to the module-carrier tape 12 as a whole, the carrier film 30 is pulled off of the adhesive layer 28 in the above-described manner. In this case, the carrier film 30 is preferably pulled off such that it is initially pulled off from areas 54 of the adhesive layer 28 adjoining the tabs 38, and only then from the tabs 38 themselves. The device 110 can comprise a suitable pulling-off device (not shown) for pulling off the carrier film 30. Alternatively, the connecting unit 114 can also be configured to pull off the carrier film 30.

FIG. 14 shows the method according to the invention for applying an adhesive layer 28 to a module-carrier tape 12 provided with a plurality of chip modules 8. In a step 124, tabs 38 are formed in the adhesive layer 28 such that the tabs 38 correspond to the chip modules 8 or their potting compounds 24 of the module-carrier tape 12. The punched contact holes 32 are aligned here so that they surround the contacts 26 in each case, as shown in FIGS. 4 and 6 to 12, for example. In subsequent step 126, the adhesive layer 28 is connected to the module-carrier tape 12 such that the tabs 38 rest on the surfaces 14 of the chip modules 8 and the sections 54 of the adhesive layer 28 adjoining the tabs 38 rest on the surface 16 of the surrounding base areas 18 of the module-carrier tape 12. The method can furthermore comprise the pulling of the carrier film 30 off of the adhesive layer 28 after the connection of the adhesive layer 28 to the module-carrier tape 12.

This method is carried out by the device shown in FIG. 13. In this case, in particular tabs 38 are formed as described with reference to FIGS. 4A to 11B.

A method according to the invention for producing a portable data carrier 2, such as a security document as shown in FIG. 1, initially comprises the step of providing a data carrier body having at least one cavity, which can preferably accommodate a chip module 8 in a precisely-fitted manner. The data carrier body furthermore comprises electrical structures having contacts which can be contacted with the chip module 8. The chip module 8, which is to be inserted into the cavity and is provided with an adhesive layer 28, is provided in that it is suitably isolated from a module-carrier tape 12 provided according to the invention with an adhesive layer 28. For this purpose, for example, individual chip modules are punched or separated in another manner out of the module-carrier tape 12 provided with the adhesive layer 28, which chip modules fit in a substantially precisely-fitted manner into cavities of data carrier bodies. The isolated chip module 8 is finally inserted into the data carrier body with its adhesive layer 28 oriented into the interior of the cavity, wherein a possible carrier film 30 is already removed and the exposed contact elements 26 of the chip module 8 contact the contacts of the electrical structures of the data carrier body provided in the cavity.

It is obvious that the present disclosure is not restricted to the individual embodiments described herein. Combinations of individual features of multiple embodiments are possible. It is thus conceivable, for example, to combine individual features of two or three cutting patterns in order to form a new advantageous cutting pattern. Other feature combinations are also conceivable. The features described for the embodiments are to be viewed as optional, if not defined to the contrary in the independent claims.

1.-19. (canceled)

20. A method for applying an adhesive layer to a module-carrier tape provided with a plurality of chip modules,
wherein surfaces of the chip modules are elevated in relation to the surface of base areas of the module-carrier tape substantially surrounding the plurality of chip modules,
wherein the method comprises the following steps:
forming tabs in the adhesive layer such that the tabs correspond to chip modules of the module-carrier tape;
connecting the adhesive layer to the module-carrier tape such that the tabs rest on the surfaces of the chip modules and sections of the adhesive layer adjoining the tabs rest on the base areas of the module-carrier tape.

21. The method according to claim 20, furthermore comprising the step of forming contact openings in the adhesive layer such that the contact openings surround electrical contact elements of the chip modules upon the connection of the adhesive layer to the module-carrier tape, so that the contact elements remain uncovered by the adhesive layer.

22. The method according to claim 20, wherein the tabs are formed by introducing openings into the adhesive layer and/or are formed by cutting patterns in the adhesive layer such that the cutting patterns expand upon the connection of the adhesive layer to the module-carrier tape to form openings such that the sections of the adhesive layer adjoining the tabs rest on the base areas of the module-carrier tape.

23. The method according to claim 22, wherein the cutting patterns expand upon the connection of the adhesive layer to form openings such that the adhesive layer rests on flanks of the chip modules which form transitions from the surfaces of the chip modules to the surface of the base areas of the module-carrier tape.

24. The method according to claim 20, wherein the adhesive layer is arranged as a transfer layer on a carrier film during the formation of the tabs, and
wherein the method furthermore comprises the step of pulling off the carrier film in a pulling-off direction from the adhesive layer after the connection of the adhesive layer to the substrate.

25. The method according to claim 24, wherein the tabs resting on the chip modules each point with their distal ends in a respective predetermined direction, wherein
(i) the predetermined direction is orthogonal to the pulling-off direction or
(ii) the predetermined direction extends at an acute angle to the pulling-off direction or
(iii) the predetermined direction corresponds to the pulling-off direction.

26. The method according to claim 24, wherein the tabs resting on the chip modules each have outer edges, which
(i) extend parallel to the pulling-off direction;
(ii) extend at an obtuse angle to the pulling-off direction;
(iii) extend in a curve, wherein tangents of the outer edges extend parallel or at an acute angle to the pulling-off direction.

27. The method according to claim 20, wherein the tabs are formed mirror-symmetrical, and/or the tabs are formed so that the respective width thereof decreases in the direction of a distal end of the respective tab.

28. The method according to claim 20, wherein the adhesive layer is connected to the module-carrier tape such that, of the adhesive layer, only the tabs rest on the surfaces of the respective chip modules and cover them substantially completely,
wherein the flanks form transitions from the surfaces of the chip modules to the surface of the base areas of the module-carrier tape.

29. The method according to claim 20, wherein upon the connection of the adhesive layer to the module-carrier tape, the tabs are pressed onto the surface of the chip modules,
wherein at the same time the sections of the adhesive layer adjoining the tabs are each pressed onto the surface of the base area of the module-carrier tape and/or flanks of the chip modules,
wherein the flanks form transitions from the surfaces of the chip modules to the surface of the base areas of the module-carrier tape.

30. A device for applying an adhesive layer to a module-carrier tape provided with a plurality of chip modules, comprising:
a processing unit, which is configured to form tabs in the adhesive layer such that the tabs correspond to the chip modules of the module-carrier tape,
a connecting unit, which is configured to connect the adhesive layer to the module-carrier tape such that the tabs rest on surfaces of the chip modules, which are elevated in relation to the surface of base areas of the module-carrier tape substantially surrounding the plurality of chip modules, and sections of the adhesive layer adjoining the tabs rest on the base areas of the module-carrier tape.

31. The device according to claim 30, comprising a heat-conducting stamp, which is configured to press the tabs onto the surfaces of the chip modules and to press the sections of the adhesive layer adjoining the tabs onto the base areas of the module-carrier tape.

32. The device according to claim 30, wherein the device is configured to carry out a method for applying an adhesive layer to a module-carrier tape provided with a plurality of chip modules,
wherein surfaces of the chip modules are elevated in relation to the surface of base areas of the module-carrier tape substantially surrounding the plurality of chip modules,
wherein the method comprises the following steps:
forming tabs in the adhesive layer such that the tabs correspond to chip modules of the module-carrier tape;
connecting the adhesive layer to the module-carrier tape such that the tabs rest on the surfaces of the chip modules and sections of the adhesive layer adjoining the tabs rest on the base areas of the module-carrier tape.

33. A module-carrier tape connected to an adhesive layer, wherein the module-carrier tape is provided with a plurality of chip modules and surfaces of the chip modules are elevated in relation to the surface of base areas of the module-carrier tape substantially surrounding the plurality of chip modules, and
the adhesive layer comprises tabs, which correspond to the chip modules of the module-carrier tape and are connected to the module-carrier tape such that the tabs rest on the surfaces of the chip modules and sections of the adhesive layer adjoining the tabs rest on the base areas of the module-carrier tape.

34. The module-carrier tape connected to an adhesive layer according to claim 33, produced according to a method for applying an adhesive layer to a module-carrier tape provided with a plurality of chip modules,
wherein surfaces of the chip modules are elevated in relation to the surface of base areas of the module-carrier tape substantially surrounding the plurality of chip modules,
wherein the method comprises the following steps:
forming tabs in the adhesive layer such that the tabs correspond to chip modules of the module-carrier tape;
connecting the adhesive layer to the module-carrier tape such that the tabs rest on the surfaces of the chip modules and sections of the adhesive layer adjoining the tabs rest on the base areas of the module-carrier tape;
and/or produced using a device for applying an adhesive layer to a module-carrier tape provided with a plurality of chip modules, comprising:
a processing unit, which is configured to form tabs in the adhesive layer such that the tabs correspond to the chip modules of the module-carrier tape,
a connecting unit, which is configured to connect the adhesive layer to the module-carrier tape such that the tabs rest on surfaces of the chip modules, which are elevated in relation to the surface of base areas of the module-carrier tape substantially surrounding the plurality of chip modules, and sections of the adhesive layer adjoining the tabs rest on the base areas of the module-carrier tape.

35. An adhesive layer to be applied to a module-carrier tape provided with a plurality of chip modules,
wherein the adhesive layer comprises tabs and is designed to be connected to the module-carrier tape such that the tabs rest on surfaces of the chip modules and sections of the adhesive layer adjoining the tabs rest on base areas of the module-carrier tape surrounding the chip modules,
wherein the tabs are formed by cutting patterns introduced into the adhesive layer such that they expand upon the connection to the module-carrier tape to form openings such that the sections of the adhesive layer adjoining the tabs rest on the base areas of the module-carrier tape.

36. The adhesive layer according to claim 35, which is suitable for being connected to a module-carrier tape using a method a method for applying an adhesive layer to a module-carrier tape provided with a plurality of chip modules,
wherein surfaces of the chip modules are elevated in relation to the surface of base areas of the module-carrier tape substantially surrounding the plurality of chip modules,
wherein the method comprises the following steps:
forming tabs in the adhesive layer such that the tabs correspond to chip modules of the module-carrier tape;
connecting the adhesive layer to the module-carrier tape such that the tabs rest on the surfaces of the chip modules and sections of the adhesive layer adjoining the tabs rest on the base areas of the module-carrier tape;
and/or using a device for applying an adhesive layer to a module-carrier tape provided with a plurality of chip modules, comprising:
a processing unit, which is configured to form tabs in the adhesive layer such that the tabs correspond to the chip modules of the module-carrier tape,
a connecting unit, which is configured to connect the adhesive layer to the module-carrier tape such that the tabs rest on surfaces of the chip modules, which are elevated in relation to the surface of base areas of the module-carrier tape substantially surrounding the plurality of chip modules, and sections of the adhesive layer adjoining the tabs rest on the base areas of the module-carrier tape.

37. A method for producing a portable data carrier comprising a chip module, comprising the following steps:
providing a data carrier body comprising electrical structures having contacts, which can be contacted via a cavity of the data carrier body, wherein the cavity is configured to accommodate the chip module;
providing a module-carrier tape provided with an adhesive layer according to claim 33;
isolating the chip module from the module-carrier tape provided with the adhesive layer;
inserting the isolated chip module into the cavity of the data carrier body such that the chip module contacts the contacts of the electrical structures.

38. A portable data carrier produced according to a method according to claim 37.
